(19) United States
(12) Patent Application Publication
(10) Pub. No.: US 2026/0098901 A1
(43) Pub. Date: Apr. 9, 2026

(54) APPARATUSES AND METHODS FOR FACILITATING FAULT DETECTION AND STATUS RECOGNITION FOR MOTORS AND OTHER APPLICATIONS, INCLUDING MOTORS AND APPLICATIONS ASSOCIATED WITH COMMUNICATION NETWORKS AND SYSTEMS

(71) Applicant: AT&T Intellectual Property I, L.P., Atlanta, GA (US)

(72) Inventors: Rakhi Gupta, Frisco, TX (US); Debashish Bhattacharjee, Coppell, TX (US); Abhay Dabholkar, Allen, TX (US); Vladimir Sevastyanov, Fort Worth, TX (US)

(73) Assignee: AT&T Intellectual Property I, L.P., Atlanta, GA (US)

(21) Appl. No.: 18/907,625

(22) Filed: Oct. 7, 2024

(51) Int. Cl. G01R 31/34; G01H 17/00; G05B 23/02

(52) U.S. Cl. CPC G01R 31/343; G01H 17/00; G05B 23/0283

(57) ABSTRACT

Aspects of the subject disclosure may include, for example, measuring and collecting first data for each status of a given type of motor having a plurality of statuses, wherein the first data includes electrical data, mechanical data, or a combination thereof, generating a model based on the first data, storing the model, resulting in a stored model, measuring and collecting second data from a plurality of motors of the given type, applying the stored model to the second data to generate results, and storing the results. Other embodiments are disclosed.

### FIELD OF THE DISCLOSURE

The subject disclosure relates to apparatuses and methods for facilitating fault detection and status recognition for motors and other applications, including motors and applications associated with communication networks and systems.

### BACKGROUND

Vast communication networks and systems, and various communication devices, may be utilized to provision communication services. As part of provisioning communication services, motors may be utilized. Electric motors serve an important role/function in numerous critical systems within the telecommunications industry, driving essential processes that ensure seamless communication and data management across the globe. Key applications within this sector include power systems, environmental (e.g., cooling) systems for data centers and telecom facilities, antenna rotors, and optical fiber cable spooling devices. The reliability of these motors is not just a matter of efficiency, but is pivotal in preventing service interruptions, data loss, and the maintenance of beneficial (e.g., optimal) operational conditions, thereby averting substantial economic repercussions and ensuring safety.

Given an ever-present load and the necessity for uninterrupted operation in many of these applications, an early detection of faults in motors is of paramount importance. Vibration analysis and electrical parameters analysis stand out as the most effective techniques for identifying mechanical defects in these motors. However, the implementation of automatic diagnoses poses significant challenges, especially in the dynamic and demanding environments of telecom infrastructure.

The task of fault diagnosis in electric motors typically involves an application of pattern recognition to classify features extracted from vibration measurements. The conventional state of the art showcases various artificial intelligence methods applied to this end, including neural networks, support vector machines, random forest techniques, and deep learning algorithms. These conventional techniques often struggle in practical scenarios due to the prevalence of imbalanced datasets, where instances of fault patterns are exceedingly rare. Furthermore, the performance of conventional classification methods has been satisfactory primarily in controlled experiments, where datasets are more balanced, and critical parameters like rotation speed, system load, and the characteristics of assembly components are well-defined. In real-world, practical industry monitoring applications, such detailed information often is not readily available for/to diagnostic tools.

Another aspect of current methodologies is the reliance on feature extraction techniques, such as Fourier transform, wavelet transform, S-transform, and Clarke transformation, along with dimensionality reduction strategies like Principal Component Analysis (PCA). Choosing the most suitable feature extraction method for a specific electric motor or rotational device in the telecom sector is complex, requiring extensive time-consuming and labor-intensive experimentation and analysis. In brief, such conventional approaches are costly and burdensome, and often fail to deliver accurate results/modeling.

### BRIEF DESCRIPTION OF THE DRAWINGS

Reference will now be made to the accompanying drawings, which are not necessarily drawn to scale, and wherein:

FIG. 1 is a diagram illustrating exemplary electrical values associated with a motor for generating a status of the motor in accordance with various aspects described herein.

FIG. 2 is a diagram illustrating exemplary vibratory/vibration values associated with a motor for generating a status of the motor in accordance with various aspects described herein.

FIG. 3A depicts various states of operation of one or more motors in accordance with various aspects described herein.

FIG. 3B and FIG. 3C depict illustrative embodiments of methods in accordance with various aspects described herein.

FIG. 4 is a block diagram of an example, non-limiting embodiment of a computing environment in accordance with various aspects described herein.

### DETAILED DESCRIPTION

By way of introduction, aspects of this disclosure provide one or more algorithms (e.g., a fault diagnosis algorithm), tailored for electric motors and rotating machinery. The algorithm(s) may provide support for operations associated with various communication networks and systems, in conjunction with practical applications involving power systems, environmental (e.g., cooling) systems for data centers and telecom facilities, antenna rotors, and optical fiber cable spooling devices, for example. The algorithms may be designed and implemented to scrutinize measurements from various devices and components and may be used to determine operational status—e.g., whether a given device or component is functioning within normal/acceptable parameters or is exhibiting potential issues.

In various embodiments of this disclosure, an algorithm may process data from an input table comprising various features and a target variable. Each feature may represent a measurement from, e.g., a device, such as voltage, current, or vibration values. The data may encapsulate the operational conditions of the device under different statuses, including a baseline ‘normal condition’. The target variable may be labeled to reflect the status of the device corresponding to the collected data, facilitating the identification of any operational anomalies. This algorithm may be repeated for each device that is the potential subject or target of analysis.

In some embodiments, an algorithm may be bifurcated into two parts/portions. A first part (referred to herein as Part A) may correspond to a model construction/generation. A second part (referenced to herein as Part B) may correspond to status classification.

In Part A, a data collection procedure may be used to gather information/data from devices across a spectrum of known issues, alongside data from devices in a normal operation/state. A target variable may be created/generated with labels indicating the device's status for each data entry. A multiclass classification model may be constructed that may be capable of discerning the device's status based on the aforementioned data.

In Part B, a data acquisition procedure may be used to collect operational data from a device under examination/test. The model generated in conjunction with Part A may be utilized on the collected data to ascertain the device's operational status.

The algorithm described above may operate on raw data that may be obtained (e.g., directly obtained) from devices, reducing (e.g., eliminating) a need for intricate preprocessing or feature extraction techniques. This approach not only simplifies diagnostic processes, but also significantly enhances classification accuracy. Moreover, the algorithm boasts robustness and computational efficiency, enabling an accurate determination of a device's status across varying loads-even those divergent from the loads observed during the model's training phase. This is particularly beneficial in the telecom industry, where electric motors and rotating machinery are expected to operate under consistent loads, making the algorithm an invaluable tool for maintaining the reliability and efficiency of telecom infrastructure.

This disclosure outlines a fault recognition approach that may be utilized for three-phase induction motors, which play a pivotal role in various sectors, including the telecom industry. For the sake of simplicity and to facilitate a clearer understanding, the machinery in question may be referred to herein as one or more “electric motors” throughout. That said, it is understood and appreciated that the scope of this disclosure extends beyond generic electric motors to encompass specialized applications critical to the telecom industry, such as telecom power systems, environmental systems for data centers and telecom facilities, antenna rotors, and optical fiber cable spooling devices, to name a few.

To facilitate analyses, a dataset (e.g., a public dataset) comprising electrical and mechanical or vibration signals collected from experiments on three-phase induction motors may be obtained/acquired. These experiments may be meticulously designed/configured to cover a range of operational scenarios, including various mechanical loads on a motor axis and different levels of broken bar defects in the motor rotor, as well as data from defect-free rotors. The tests conducted may provide a comprehensive dataset that captures a wide spectrum of potential fault conditions and their signatures/characteristics in electric motors.

The insights gained, and the fault recognition methodologies developed, herein may be applied to various electric motors, inclusive of motors used in the specific applications within the telecom industry mentioned above. The versatility of the approaches set forth herein are based on an ability to adapt to different operational and fault conditions, thereby facilitating valuable tools for ensuring the reliability and efficiency of telecom-related electric motors.

By leveraging publicly available experimental data, it is appreciated that the techniques and know-how developed herein are not only effective for electric motors in general, but can also be leveraged to achieve particular results when applied to specialized electric motors, inclusive of motors operating within the telecom sector. The detailed analysis and methodologies presented herein provide a robust framework for diagnosing and addressing faults in practical applications involving electric motors, thereby supporting the continuous operation and maintenance of telecom infrastructure.

For purposes of facilitating the explanation that follows, it may be assumed that six variables may be defined as follows: (1) phase A voltage Va, (2) phase B voltage Vb, (3) phase C voltage Vc, (4) current in phase A Ia, (5) current in phase B Ib, and (6) current in phase C Ic. As one of skill in the art will appreciate, each of these variables may refer to one of the phases associated with a motor (e.g., a first phase—phase A, a second phase—phase B, and a third phase—phase C) that may be separated by a phase difference of, e.g., 120 degrees.

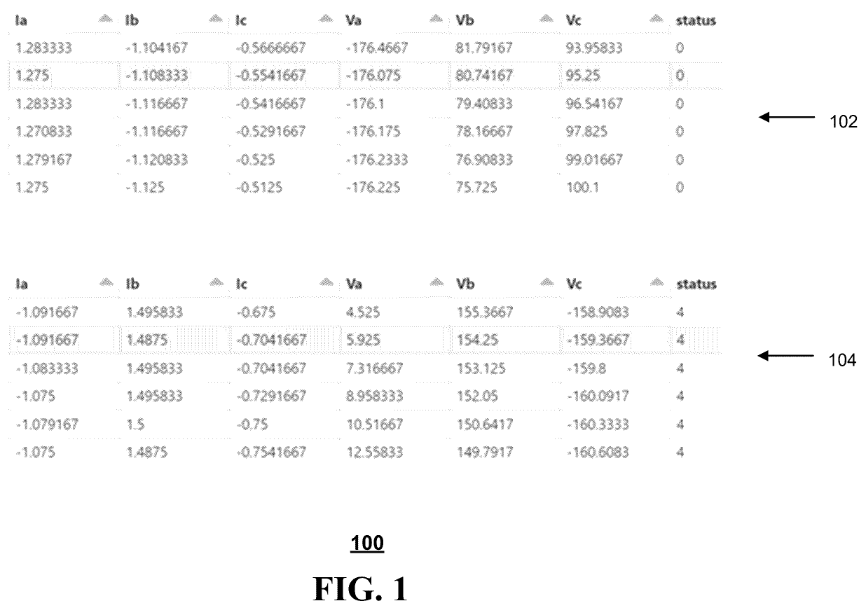

With the foregoing in mind, reference may be made to FIG. 1, which depicts a diagram 100 of various values for the aforementioned variables. The diagram 100 is partitioned into a first section 102 and a second section 104, corresponding to the first six rows and the last six rows of values in a given instance/embodiment, respectively, which is to say that other rows of values have been omitted from FIG. 1 for the sake of simplicity/brevity. In the diagram 100, the condition of status=0 (corresponding to the rows in the section 102) may be representative of a motor operating within/under normal conditions (e.g., operating within a given tolerance or envelope), whereas the condition of status=4 (corresponding to the rows in the section 104) may be representative of the motor operating with, e.g., four broken bars.

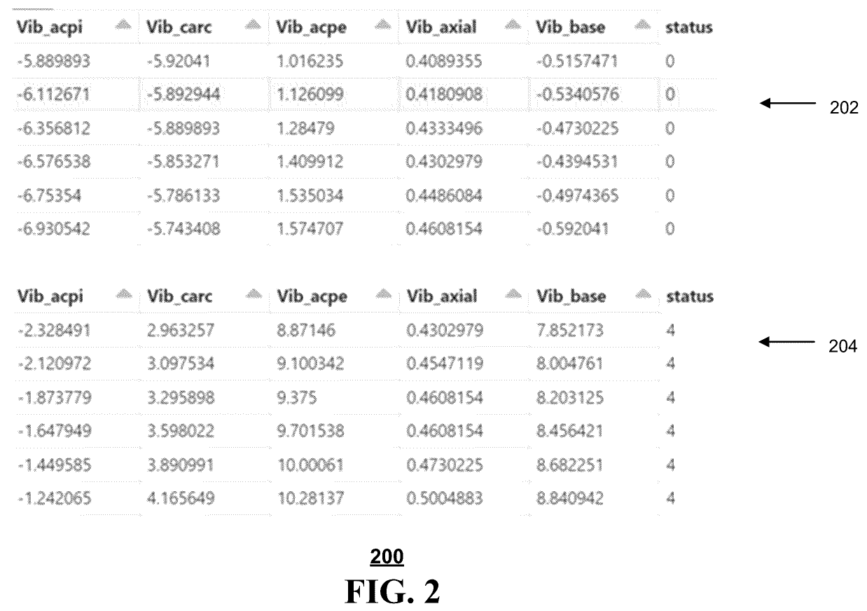

Similarly, and with reference to FIG. 2, a diagram 200 is shown of various values associated with a motor in respect of a number of variables, such as variables Vib_acpi (corresponding to a radial mechanical vibration speed on a driven side), Vib_carc (corresponding to a tangential mechanical vibration speed in a housing), Vib_acpe (corresponding to a radial mechanical vibration speed on a non-driven side), Vib_axial (corresponding to an axial mechanical vibration speed on a driven side), and Vib_base (corresponding to a tangential mechanical vibration speed at a base). The diagram 200 is partitioned into a first section 202 and a second section 204, corresponding to the first six rows and the last six rows of values in a given instance/embodiment, respectively, which is to say that other rows of values have been omitted from FIG. 2 for the sake of simplicity/brevity. In the diagram 200, the condition of status=0 (corresponding to the rows in the section 202) may be representative of a motor operating within/under normal conditions (e.g., operating within a given tolerance or envelope), whereas the condition of status=4 (corresponding to the rows in the section 204) may be representative of the motor operating with, e.g., four broken bars.

The diagrams 100 and 200 may correspond to a same/common motor in some instances. In some instances, the diagram 100 may correspond to a first motor and the diagram 200 may correspond to a second motor that is different from the first motor. The values shown in FIGS. 1 and 2 are illustrative, which is to say that other values may be used in any given embodiment. Further, while two states/statuses (e.g., normal, broken bar(s)) were referenced above, it is understood and appreciated that any number of states/statuses may be referenced/utilized within a given embodiment, as will become clearer in the description that follows.

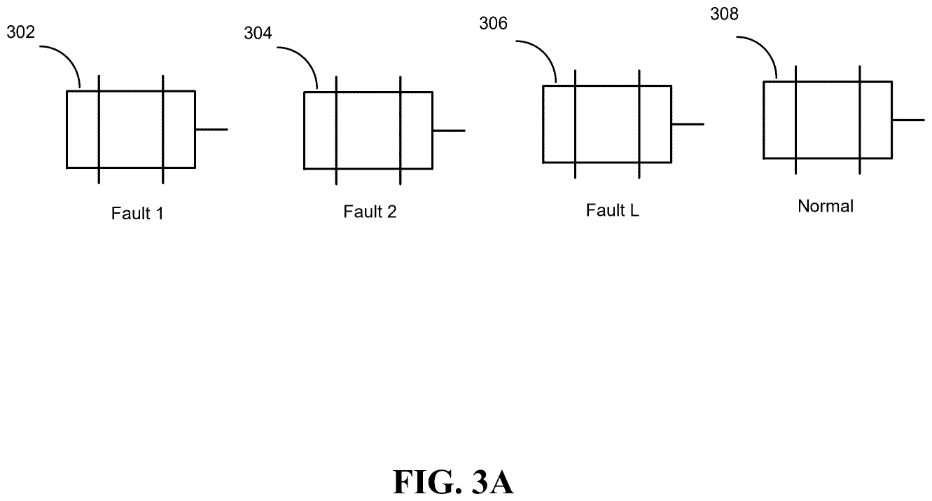

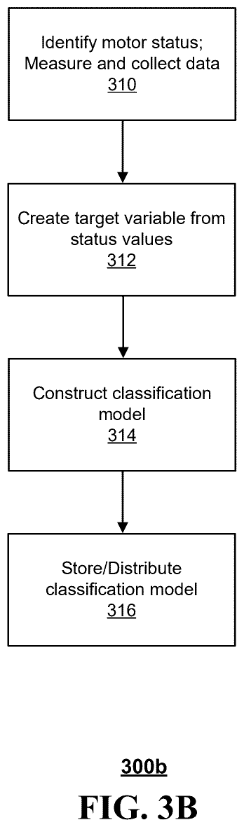

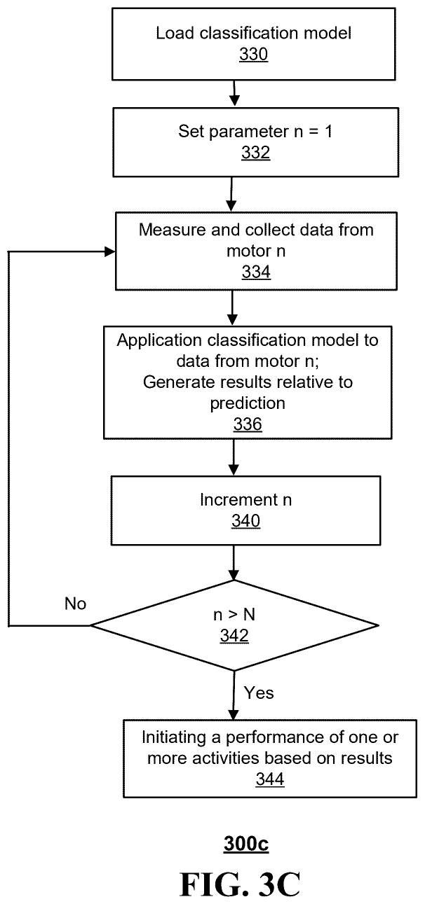

Continuing with the examples above, and with reference to FIG. 3A, four motors are represented via reference characters 302, 304, 306, and 308. The motors 302, 304, 306, and 308 may correspond to a same type or kind of motor (e.g., a motor of a given make and model number), in/under different operating states, statuses, or conditions. For example, the reference character 302 may correspond to a first fault (Fault 1), the reference character 304 may correspond to a second fault (Fault 2), . . . the reference character 306 may correspond to an L^{th} fault (Fault L), and the reference character 308 may correspond to a normal state (Normal). While four states/statuses are illustratively represented in FIG. 3A, any number of states/statuses may be utilized in a given embodiment.

With reference to FIG. 3B, a method 300b is shown. The method 300b may be utilized in conjunction with one or more motors, such as motors in/under different operating states, statuses, or conditions as demonstrated in FIG. 3A. Various operations associated with the method 300b are described below in relation to the blocks shown in FIG. 3B.

In block 310, a motor representing a particular type of status may be identified. Data (e.g., electric and/or vibration data) may be measured and collected for the motor of the identified status.

In block 312, a target variable may be created/generated from the status values. Block 312 may include assigning status values to the target variable—see the ‘status’ column for the various rows of the diagrams 100 and 200 in FIG. 1 and FIG. 2, respectively, as examples.

Operations associated with the blocks 310 and 312 may be repeated for each type of motor status (see the four motor statuses 302, 304, 306, and 308 represented in FIG. 3A, for example).

In block 314, a multiclass classification model may be generated/constructed on the data and values collected/generated via blocks 310 and 312.

In block 316, the model generated as part of block 314 may be saved/stored and/or distributed for additional uses.

Aspects of model generation may leverage machine learning (ML) and/or artificial intelligence (AI) technologies. For example, aspects of this disclosure may utilize automated machine learning (AutoML) algorithms and technologies in conjunction with a cloud-based platform to assist an entity (e.g., an enterprise) in building, scaling, and governing data and AI/ML, including generative AI and other ML based models, techniques, and algorithms. Various platforms, products, and services, as potentially provided or supported by one or more vendors or entities, may be utilized to facilitate aspects of AI and/or ML of this disclosure.

With reference to FIG. 3C, a method 300c is shown. The method 300c may be utilized in conjunction with one or more motors, such as motors in/under different operating states, statuses, or conditions. Various operations associated with the method 300c are described below in relation to the blocks shown in FIG. 3C.

In block 330, a classification model may be loaded or obtained. For example, block 330 may include obtaining the classification model from a database, a library, or the like. The model of block 330 may correspond to the model that was constructed (block 314) and stored/distributed (block 316) as part of the method 300b of FIG. 3B.

In block 332, a parameter n may be initialized. For example, the initialization may include setting the parameter equal to 1. The parameter may correspond to an index into an array of devices, motors, or the like. Each such device/motor may be associated with the model obtained as part of block 330.

In block 334, data may be measured and/or collected for the motor having the index equal to n.

In block 336, the classification model (obtained as part of block 330) may be applied to the data (of block 334). As part of block 336, one or more results may be generated relative to a prediction provided by the classification model. The results may be saved/stored as part of block 336. As part of block 336, one or more reports or messages may be generated.

In block 340, the value of the parameter n may be incremented.

In block 342, a determination may be made whether the value of the parameter n is greater than a value N. The value N in this context may refer to the count or universe of the motors included in the array. In this respect, and as one skilled in the art will appreciate, the increment of the parameter n in block 340 serves to step through each of the motors of the array in sequence until the termination point corresponding to the last motor of the array is reached.

Assuming that the determination of block 342 is answered in the affirmative, flow may proceed to block 344. Otherwise, flow may proceed from block 342 to block 334 to collect data for the next motor in the sequence/array.

In block 344, the results (of block 336) may be analyzed and one or more activities may be performed. For example, and to the extent that for a given motor (n) the block 336 indicates that the results exceed or depart from the prediction (potentially relative to one or more ranges or thresholds), block 344 may include performing tests, dispatching personnel to the site/location of the given motor (n), performing a maintenance or repair activity in respect of the motor (n), replacing the motor (n) with a new motor, etc.

While for purposes of simplicity of explanation, the respective processes are shown and described as a series of blocks in FIGS. 3B and 3C, it is to be understood and appreciated that the claimed subject matter is not limited by the order of the blocks, as some blocks may occur in different orders and/or concurrently with other blocks from what is depicted and described herein. Moreover, not all illustrated blocks may be required to implement the methods described herein. One or more operations or blocks may be based on one or more other operations or blocks in a given embodiment. While described separately, aspects of the method 300b may be combined with aspects of the method 300c in some embodiments.

The various blocks or operations of the methods 300b and 300c may be implemented or executed, in whole or in part, in conjunction with one or more processing systems. A processing system may include one or more processors, and a memory that stores instructions that, when executed by the one or more processors, facilitates a performance of the blocks or operations of the methods. In some embodiments, a transitory and/or non-transitory computer or machine-readable medium may be used to store the instructions.

It is appreciated that in generating a model, that the model might not be constructed with an accuracy equal to 100%. For example, there may be practical limitations in terms of the number of datasets or trial sets that may be utilized during a testing or characterization phase. Moreover, there will inherently be noise that is present that might not allow for a model to be constructed having 100% accuracy. What this means in practice is that a model may suffer from a certain degree of inaccuracy in practical applications. Experimentation has demonstrated that a model of approximately 95% accuracy may be realized. In terms of a generation of results (see, e.g., block 336 of FIG. 3C), this means that there may be instances of false negatives or false positives (meaning that a given motor under test or observation may be misclassified—e.g., may be deemed to be operating under a first status [e.g., a broken bar status], when in reality the motor is operating with a second status [e.g., a normal status] that is different from the first status) when using a model. Aspects of this disclosure may incorporate error correction, such that a model that is constructed might not be static. Instead, the model may be adapted or modified over time, as new data or results are obtained. In this respect, any errors (e.g., false negatives or false positives) that may be generated may decrease/diminish in time, which is to say that a model may approach a theoretical accuracy value of 100% as the model is refined.

As set forth above, practical applications of the various aspects of this disclosure may be utilized to generate status regarding operations of motors over a lifetime of the motors. Motor status tends to change ‘slowly’—e.g., there is typically very little variation or drift in motor parameters/characteristics (e.g., electrical or vibration/mechanical characteristics) over time. In this respect, aspects of this disclosure (including, for example, aspects of the method 300c) may be implemented as part of a background task or procedure to generally check on the status or health of a fleet of motors (or more generally, assets or resources) over time, potentially periodically or as part of a schedule.

Aspects of this disclosure may be used to pinpoint those motors (or other assets or resources) that are likely to experience degraded status or health relative to a universe of motors under evaluation or observation. As one skilled in the art will appreciate, there may be hundreds or even thousands of motors that may be under observation. In this regard, it is impractical to assess health status for each motor manually, on an individual basis. Thus, aspects of this disclosure may be operated at scale to facilitate automated health status checking and monitoring, while providing valuable information/insight as to the nature of any problems or issues that may arise with a heightened degree of specificity. In this regard, maintenance and troubleshooting activities may be enhanced via the features of this disclosure, thereby representing substantial improvements to technology as part of various practical applications.

To the extent that a resource, an asset, a motor, or the like is modified, a modification may be made to a model that may be used to observe or evaluate parameters or characteristics. In this regard, aspects of this disclosure may encourage further improvements or enhancements to technology.

In various embodiments, such as for example in relation to testing or qualification activities, values for parameters or characteristics of, e.g., motors may be captured. Those values (or, analogously, datasets or data points) that appear to correspond to, or are similar to, one another within a threshold, may be indicative of the values that are assigned to a given operating state/status/condition.

Aspects of this disclosure may be used to predict when a motor (or other asset or resource) is likely to become inoperable in an amount greater than a threshold. In this respect, proactive actions/activities may be undertaken in advance of the inoperability manifesting itself in terms of impact on an end-user, an application, or a service. In this regard, and in relation to motors utilized as part of a communication network or system, quality of service, quality of experience and reliability in data transfer operations may be enhanced.

Aspects of this disclosure may be applied as part of various practical applications. Some of the examples set forth above pertained to motors (e.g., three-phase induction motors). The various embodiments of this disclosure may be applied as part of other practical applications, including applications pertaining to generators, transportation systems, robotics, factory assembly lines, etc. Aspects of this disclosure may have particular applicability in respect of applications involving highly repeatable datasets (e.g., datasets or datapoints that occur with regularity over an operating envelope or range).

As demonstrated herein, the various aspects of this disclosure represent substantial improvements to technology in respect of various practical applications. In this regard, and as one of skill in the art will readily appreciate based upon a review of this disclosure, the various aspects of this disclosure are not directed to abstract ideas. To the contrary, the various aspects of this disclosure are transformative in nature and bring about useful, concrete, and tangible results in respect of generating status regarding operations of various types of assets and resources.

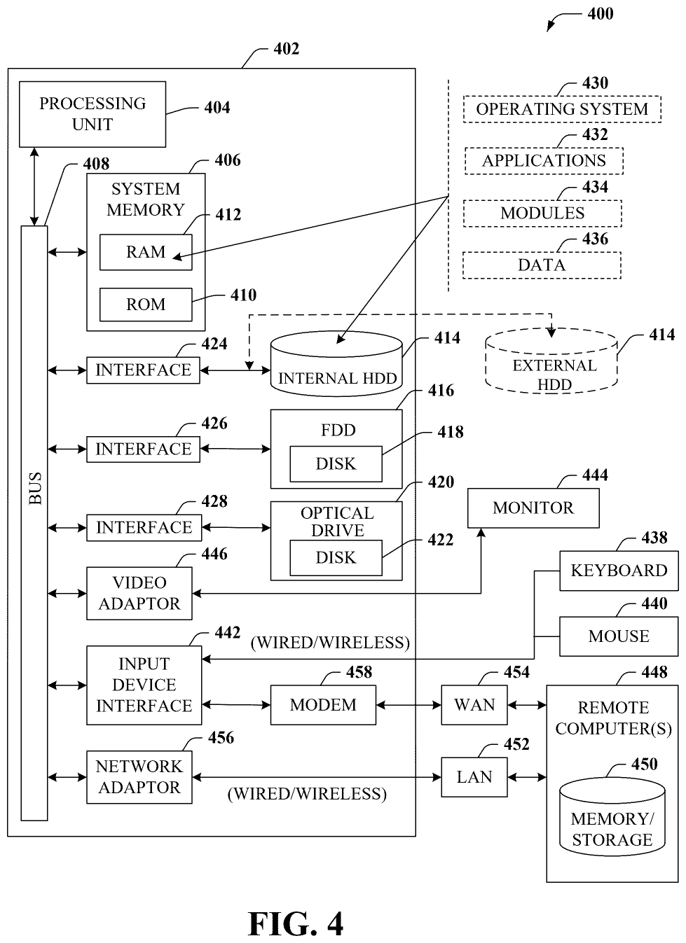

Turning now to FIG. 4, there is illustrated a block diagram of a computing environment in accordance with various aspects described herein. In order to provide additional context for various embodiments of the embodiments described herein, FIG. 4 and the following discussion are intended to provide a brief, general description of a suitable computing environment 400 in which the various embodiments of the subject disclosure can be implemented. For example, the computing environment 400 can facilitate, in whole or in part, measuring and collecting first data for each status of a given type of motor having a plurality of statuses, wherein the first data includes electrical data, mechanical data, or a combination thereof; generating a model based on the first data; storing the model, resulting in a stored model; measuring and collecting second data from a plurality of motors of the given type; applying the stored model to the second data to generate results; and storing the results. The computing environment 400 can facilitate, in whole or in part, obtaining a model of a rotating machine of a given type, wherein the model includes values for parameters of the rotating machine in terms of a plurality of statuses; measuring and collecting data from a plurality of rotating machines of the given type; applying the model to the data; based on the applying, predicting that a rotating machine included in the plurality of rotating machines has a given status included in the plurality of statuses; and generating a message or a report that identifies the rotating machine included in the plurality of rotating machines and the given status. The computing environment 400 can facilitate, in whole or in part, collecting, by a processing system including a processor, data from a plurality of motors used as part of a communication network or system; applying, by the processing system, a model of the motors to the data; based on the applying, predicting, by the processing system, that a motor included in the plurality of motors has a status included in a plurality of statuses; and based on the predicting, initiating, by the processing system, an activity in respect of the motor included in the plurality of motors.

Generally, program modules comprise routines, programs, components, data structures, etc., that perform particular tasks or implement particular abstract data types. Moreover, those skilled in the art will appreciate that the methods can be practiced with other computer system configurations, comprising single-processor or multiprocessor computer systems, minicomputers, mainframe computers, as well as personal computers, hand-held computing devices, microprocessor-based or programmable consumer electronics, and the like, each of which can be operatively coupled to one or more associated devices.

As used herein, a processing circuit includes one or more processors as well as other application specific circuits such as an application specific integrated circuit, digital logic circuit, state machine, programmable gate array or other circuit that processes input signals or data and that produces output signals or data in response thereto. It should be noted that while any functions and features described herein in association with the operation of a processor could likewise be performed by a processing circuit.

The illustrated embodiments of the embodiments herein can be also practiced in distributed computing environments where certain tasks are performed by remote processing devices that are linked through a communications network. In a distributed computing environment, program modules can be located in both local and remote memory storage devices.

Computing devices typically comprise a variety of media, which can comprise computer-readable storage media and/or communications media, which two terms are used herein differently from one another as follows. Computer-readable storage media can be any available storage media that can be accessed by the computer and comprises both volatile and nonvolatile media, removable and non-removable media. By way of example, and not limitation, computer-readable storage media can be implemented in connection with any method or technology for storage of information such as computer-readable instructions, program modules, structured data or unstructured data.

Computer-readable storage media can comprise, but are not limited to, random access memory (RAM), read only memory (ROM), electrically erasable programmable read only memory (EEPROM), flash memory or other memory technology, compact disk read only memory (CD ROM), digital versatile disk (DVD) or other optical disk storage, magnetic cassettes, magnetic tape, magnetic disk storage or other magnetic storage devices or other tangible and/or non-transitory media which can be used to store desired information. In this regard, the terms “tangible” or “non-transitory” herein as applied to storage, memory or computer-readable media, are to be understood to exclude only propagating transitory signals per se as modifiers and do not relinquish rights to all standard storage, memory or computer-readable media that are not only propagating transitory signals per se.

Computer-readable storage media can be accessed by one or more local or remote computing devices, e.g., via access requests, queries or other data retrieval protocols, for a variety of operations with respect to the information stored by the medium.

Communications media typically embody computer-readable instructions, data structures, program modules or other structured or unstructured data in a data signal such as a modulated data signal, e.g., a carrier wave or other transport mechanism, and comprises any information delivery or transport media. The term “modulated data signal” or signals refers to a signal that has one or more of its characteristics set or changed in such a manner as to encode information in one or more signals. By way of example, and not limitation, communication media comprise wired media, such as a wired network or direct-wired connection, and wireless media such as acoustic, RF, infrared and other wireless media.

With reference again to FIG. 4, the example environment can comprise a computer 402, the computer 402 comprising a processing unit 404, a system memory 406 and a system bus 408. The system bus 408 couples system components including, but not limited to, the system memory 406 to the processing unit 404. The processing unit 404 can be any of various commercially available processors. Dual microprocessors and other multiprocessor architectures can also be employed as the processing unit 404.

The system bus 408 can be any of several types of bus structure that can further interconnect to a memory bus (with or without a memory controller), a peripheral bus, and a local bus using any of a variety of commercially available bus architectures. The system memory 406 comprises ROM 410 and RAM 412. A basic input/output system (BIOS) can be stored in a non-volatile memory such as ROM, erasable programmable read only memory (EPROM), EEPROM, which BIOS contains the basic routines that help to transfer information between elements within the computer 402, such as during startup. The RAM 412 can also comprise a high-speed RAM such as static RAM for caching data.

The computer 402 further comprises an internal hard disk drive (HDD) 414 (e.g., EIDE, SATA), which internal HDD 414 can also be configured for external use in a suitable chassis (not shown), a magnetic floppy disk drive (FDD) 416, (e.g., to read from or write to a removable diskette 418) and an optical disk drive 420, (e.g., reading a CD-ROM disk 422 or, to read from or write to other high-capacity optical media such as the DVD). The HDD 414, magnetic FDD 416 and optical disk drive 420 can be connected to the system bus 408 by a hard disk drive interface 424, a magnetic disk drive interface 426 and an optical drive interface 428, respectively. The hard disk drive interface 424 for external drive implementations comprises at least one or both of Universal Serial Bus (USB) and Institute of Electrical and Electronics Engineers (IEEE) 1394 interface technologies. Other external drive connection technologies are within contemplation of the embodiments described herein.

The drives and their associated computer-readable storage media provide nonvolatile storage of data, data structures, computer-executable instructions, and so forth. For the computer 402, the drives and storage media accommodate the storage of any data in a suitable digital format. Although the description of computer-readable storage media above refers to a hard disk drive (HDD), a removable magnetic diskette, and a removable optical media such as a CD or DVD, it should be appreciated by those skilled in the art that other types of storage media which are readable by a computer, such as zip drives, magnetic cassettes, flash memory cards, cartridges, and the like, can also be used in the example operating environment, and further, that any such storage media can contain computer-executable instructions for performing the methods described herein.

A number of program modules can be stored in the drives and RAM 412, comprising an operating system 430, one or more application programs 432, other program modules 434 and program data 436. All or portions of the operating system, applications, modules, and/or data can also be cached in the RAM 412. The systems and methods described herein can be implemented utilizing various commercially available operating systems or combinations of operating systems.

A user can enter commands and information into the computer 402 through one or more wired/wireless input devices, e.g., a keyboard 438 and a pointing device, such as a mouse 440. Other input devices (not shown) can comprise a microphone, an infrared (IR) remote control, a joystick, a game pad, a stylus pen, touch screen or the like. These and other input devices are often connected to the processing unit 404 through an input device interface 442 that can be coupled to the system bus 408, but can be connected by other interfaces, such as a parallel port, an IEEE 1394 serial port, a game port, a universal serial bus (USB) port, an IR interface, etc.

A monitor 444 or other type of display device can be also connected to the system bus 408 via an interface, such as a video adapter 446. It will also be appreciated that in alternative embodiments, a monitor 444 can also be any display device (e.g., another computer having a display, a smart phone, a tablet computer, etc.) for receiving display information associated with computer 402 via any communication means, including via the Internet and cloud-based networks. In addition to the monitor 444, a computer typically comprises other peripheral output devices (not shown), such as speakers, printers, etc.

The computer 402 can operate in a networked environment using logical connections via wired and/or wireless communications to one or more remote computers, such as a remote computer(s) 448. The remote computer(s) 448 can be a workstation, a server computer, a router, a personal computer, portable computer, microprocessor-based entertainment appliance, a peer device or other common network node, and typically comprises many or all of the elements described relative to the computer 402, although, for purposes of brevity, only a remote memory/storage device 450 is illustrated. The logical connections depicted comprise wired/wireless connectivity to a local area network (LAN) 452 and/or larger networks, e.g., a wide area network (WAN) 454. Such LAN and WAN networking environments are commonplace in offices and companies, and facilitate enterprise-wide computer networks, such as intranets, all of which can connect to a global communications network, e.g., the Internet.

When used in a LAN networking environment, the computer 402 can be connected to the LAN 452 through a wired and/or wireless communication network interface or adapter 456. The adapter 456 can facilitate wired or wireless communication to the LAN 452, which can also comprise a wireless AP disposed thereon for communicating with the adapter 456.

When used in a WAN networking environment, the computer 402 can comprise a modem 458 or can be connected to a communications server on the WAN 454 or has other means for establishing communications over the WAN 454, such as by way of the Internet. The modem 458, which can be internal or external and a wired or wireless device, can be connected to the system bus 408 via the input device interface 442. In a networked environment, program modules depicted relative to the computer 402 or portions thereof, can be stored in the remote memory/storage device 450. It will be appreciated that the network connections shown are example and other means of establishing a communications link between the computers can be used.

The computer 402 can be operable to communicate with any wireless devices or entities operatively disposed in wireless communication, e.g., a printer, scanner, desktop and/or portable computer, portable data assistant, communications satellite, any piece of equipment or location associated with a wirelessly detectable tag (e.g., a kiosk, news stand, restroom), and telephone. This can comprise Wireless Fidelity (Wi-Fi) and BLUETOOTH® wireless technologies. Thus, the communication can be a predefined structure as with a conventional network or simply an ad hoc communication between at least two devices.

Wi-Fi can allow connection to the Internet from a couch at home, a bed in a hotel room or a conference room at work, without wires. Wi-Fi is a wireless technology similar to that used in a cell phone that enables such devices, e.g., computers, to send and receive data indoors and out; anywhere within the range of a base station. Wi-Fi networks use radio technologies called IEEE 802.11 (a, b, g, n, ac, ag, etc.) to provide secure, reliable, fast wireless connectivity. A Wi-Fi network can be used to connect computers to each other, to the Internet, and to wired networks (which can use IEEE 802.3 or Ethernet). Wi-Fi networks operate in the unlicensed 2.4 and 5 GHz radio bands for example or with products that contain both bands (dual band), so the networks can provide real-world performance similar to the basic 10BaseT wired Ethernet networks used in many offices.

What has been described above includes mere examples of various embodiments. It is, of course, not possible to describe every conceivable combination of components or methodologies for purposes of describing these examples, but one of ordinary skill in the art can recognize that many further combinations and permutations of the present embodiments are possible. Accordingly, the embodiments disclosed and/or claimed herein are intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

Computing devices typically comprise a variety of media, which can comprise computer-readable storage media and/or communications media, which two terms are used herein differently from one another as follows. Computer-readable storage media can be any available storage media that can be accessed by the computer and comprises both volatile and nonvolatile media, removable and non-removable media. By way of example, and not limitation, computer-readable storage media can be implemented in connection with any method or technology for storage of information such as computer-readable instructions, program modules, structured data or unstructured data. Computer-readable storage media can comprise the widest variety of storage media including tangible and/or non-transitory media which can be used to store desired information. In this regard, the terms “tangible” or “non-transitory” herein as applied to storage, memory or computer-readable media, are to be understood to exclude only propagating transitory signals per se as modifiers and do not relinquish rights to all standard storage, memory or computer-readable media that are not only propagating transitory signals per se.

In addition, a flow diagram may include a “start” and/or “continue” indication. The “start” and “continue” indications reflect that the steps presented can optionally be incorporated in or otherwise used in conjunction with other routines. In this context, “start” indicates the beginning of the first step presented and may be preceded by other activities not specifically shown. Further, the “continue” indication reflects that the steps presented may be performed multiple times and/or may be succeeded by other activities not specifically shown. Further, while a flow diagram indicates a particular ordering of steps, other orderings are likewise possible provided that the principles of causality are maintained.

As may also be used herein, the term(s) “operably coupled to”, “coupled to”, and/or “coupling” includes direct coupling between items and/or indirect coupling between items via one or more intervening items. Such items and intervening items include, but are not limited to, junctions, communication paths, components, circuit elements, circuits, functional blocks, and/or devices. As an example of indirect coupling, a signal conveyed from a first item to a second item may be modified by one or more intervening items by modifying the form, nature or format of information in a signal, while one or more elements of the information in the signal are nevertheless conveyed in a manner than can be recognized by the second item. In a further example of indirect coupling, an action in a first item can cause a reaction on the second item, as a result of actions and/or reactions in one or more intervening items.

Although specific embodiments have been illustrated and described herein, it should be appreciated that any arrangement which achieves the same or similar purpose may be substituted for the embodiments described or shown by the subject disclosure. The subject disclosure is intended to cover any and all adaptations or variations of various embodiments. Combinations of the above embodiments, and other embodiments not specifically described herein, can be used in the subject disclosure. For instance, one or more features from one or more embodiments can be combined with one or more features of one or more other embodiments. In one or more embodiments, features that are positively recited can also be negatively recited and excluded from the embodiment with or without replacement by another structural and/or functional feature. The steps or functions described with respect to the embodiments of the subject disclosure can be performed in any order. The steps or functions described with respect to the embodiments of the subject disclosure can be performed alone or in combination with other steps or functions of the subject disclosure, as well as from other embodiments or from other steps that have not been described in the subject disclosure. Further, more than or less than all of the features described with respect to an embodiment can also be utilized.

What is claimed is:

1. A device, comprising:
a processing system including a processor; and
a memory that stores executable instructions that, when executed by the processing system, facilitate performance of operations, the operations comprising:
measuring and collecting first data for each status of a given type of motor having a plurality of statuses, wherein the first data includes electrical data, mechanical data, or a combination thereof;
generating a model based on the first data;
storing the model, resulting in a stored model;
measuring and collecting second data from a plurality of motors of the given type;
applying the stored model to the second data to generate results; and
storing the results.

2. The device of claim 1, wherein the first data includes the electrical data.

3. The device of claim 2, wherein the first data includes voltage data, current data, or a combination thereof.

4. The device of claim 1, wherein the first data includes the mechanical data.

5. The device of claim 4, wherein the first data includes a radial mechanical vibration speed, a tangential mechanical vibration speed, an axial mechanical vibration speed, or any combination thereof.

6. The device of claim 1, wherein the given type of the motor is a three-phase induction motor.

7. The device of claim 1, wherein the generating of the model is based on a use of machine learning, artificial intelligence, or a combination thereof.

8. The device of claim 1, wherein the results include a prediction of a respective status of each motor of the plurality of motors.

9. The device of claim 8, wherein the respective status of each motor of the plurality of motors is included in the plurality of statuses.

10. The device of claim 1, wherein the measuring and collecting of the second data from the plurality of motors of the given type and the applying of the model to the second data occur periodically.

11. The device of claim 1, wherein the operations further comprise:
subsequent to the applying of the stored model to the second data to generate the results, modifying the stored model to generate a modified model that is different from the model;
measuring and collecting third data from the plurality of motors of the given type;
applying the modified model to the third data to generate second results; and
storing the second results.

12. The device of claim 1, wherein the operations further comprise:
analyzing the results; and
based on the analyzing of the results, initiating a performance of at least one activity.

13. The device of claim 12, wherein the at least one activity includes: performing a test on a motor included in the plurality of motors, dispatching personnel to a site of the motor included in the plurality of motors, performing a maintenance or repair activity in respect of the motor included in the plurality of motors, replacing the motor included in the plurality of motors with a new motor, or any combination thereof.

14. The device of claim 12, wherein the operations further comprise:
based on the analyzing of the results, identifying a motor included in the plurality of motors that is predicted to become inoperable in an amount greater than a threshold.

15. A non-transitory machine-readable medium, comprising executable instructions that, when executed by a processing system including a processor, facilitate performance of operations, the operations comprising:
obtaining a model of a rotating machine of a given type, wherein the model includes values for parameters of the rotating machine in terms of a plurality of statuses;
measuring and collecting data from a plurality of rotating machines of the given type;
applying the model to the data;
based on the applying, predicting that a rotating machine included in the plurality of rotating machines has a given status included in the plurality of statuses; and
generating a message or a report that identifies the rotating machine included in the plurality of rotating machines and the given status.

16. The non-transitory machine-readable medium of claim 15, wherein the message or the report identifies a location of the rotating machine included in the plurality of rotating machines.

17. The non-transitory machine-readable medium of claim 15, wherein the given type of the rotating machine is one of a motor or a generator.

18. A method, comprising:
collecting, by a processing system including a processor, data from a plurality of motors used as part of a communication network or system;
applying, by the processing system, a model of the motors to the data;
based on the applying, predicting, by the processing system, that a motor included in the plurality of motors has a status included in a plurality of statuses; and
based on the predicting, initiating, by the processing system, an activity in respect of the motor included in the plurality of motors.

19. The method of claim 18, further comprising:
training, by the processing system, the model on a dataset corresponding to the plurality of statuses,
wherein the applying is based on the training.

20. The method of claim 18, wherein the data includes electrical data, vibration data, or a combination thereof, and wherein the plurality of statuses includes a status that is based on a specified number of broken bar defects.
